(19) United States
(12) Patent Application Publication
(10) Pub. No.: US 2005/0284152 A1
(43) Pub. Date: Dec. 29, 2005

(54) Temperature controlled input device for computer

(76) Inventor: Caid Christiansen, Omaha, NE (US)

Correspondence Address: HARSHAW RESEARCH INCORPORATED, P O BOX 418, OTTAWA, KS, 66067, US

(21) Appl. No.: 10/878,716

(22) Filed: Jun. 28, 2004

(51) Int. Cl. F25B 21/02; F25D 23/12; G06F 1/16; H05K 5/00; H05K 7/00

(52) U.S. Cl. 62/3.3; 62/259.2

(57) ABSTRACT

A temperature controlled computer input device includes a housing having at least one manual mechanism for generating data signals, a thermoelectric assembly, and a source of energy. The thermoelectric assembly includes two heat sinks and a Peltier effect device for creating warming and cooling configurations. The Peltier effect device includes two insulated materials spaced apart in a parallel configuration and semiconductors sandwiched between the insulated materials. The semiconductors are electrically connected in series by electrical conductors and electrically connected to the energy source. Ventilation holes and a fan are optional. Electricity flows in series through the semiconductors and electrical conductors, inducing a temperature differential between the two heat sinks. This heats the first and cools the second heat sink. Reversing the current direction cools the first and heats the second heat sink. The user selects the direction and amount of current flow to selectively warm or cool his hands.

### BACKGROUND OF THE INVENTION

This invention relates generally to computer input devices and, more particularly, to a temperature controlled input device for computers.

Modem office environments are often somewhat inhospitable places. Heavy reliance on computer technology has resulted in unprecedented levels of productivity, but this is often achieved at the expense of comfort. Temperature, in particular, is often a problem. Powerful computers need a cool environment to run effectively, and offices are often maintained at cooler temperatures than are comfortable to their human occupants. This is especially felt in the hands, where circulation is often poor and the skin is exposed. By providing a favorable microclimate, especially near the hands of the computer user, the overall cooler office temperatures could be maintained for the computers while an extra level of comfort is provided for the office workers.

In other office environments that are not properly cooled, temperatures can be higher than are comfortable to their human occupants. In such situations, a cooled computer input device would help comfort the office workers.

U.S. Pat. No. 5,193,523 proposes using vented air from the interior of a computer to heat a selected area of the workstation. This requires conduit to couple the computer to the selected workstation area and relies on the computer to produce enough excess heat to provide a warming effect for the user Both U.S. Pat. No. 5,686,005 and U.S. Pat. No. 6,115,540 proposes heating areas near computer input devices to warm the user's hands. U.S. Pat. No. 5,686,005 discloses a heated pad placed under the computer input device and near the user's hands. The heated pad is warmed by conventional resistance-type heating elements. U.S. Pat. No. 6,115,540 places a radiative hand warming apparatus near a keyboard to warm the user's hands by radiant energy during typing. This apparatus uses infrared radiation sources and traditional resistive electric heating elements.

Other devices are known that include heat sources inside computer input devices, such as in U.S. Pat. No. 5,828,034, U.S. Pat. No. 6,646,226, and U.S. 2002/0093485. These devices all provide variations of using resistive electric heating elements to create heat and warm the user's hands. While resistive electric heating elements are simple and widely known, they are energy intensive and cannot be used for cooling.

U.S. Pat. No. 6,135,876 discloses an air-cooled mouse for a personal computer that blows air through holes in the mouse casing to cool a user's hand. This relies entirely on the blown air to cool the hand, however, and does not provide a method to heat the mouse.

Therefore, it is desirable to have a temperature controlled computer input device that can selectively warm or cool the user's hands, is safe and effective, and is efficient enough that the amount of power needed to operate the temperature control mechanism is relatively small.

### SUMMARY OF THE INVENTION

A temperature controlled input device for a computer according to the present invention includes a housing having at least one manually manipulative mechanism for generating data signals for transmission to the computer, a thermoelectric assembly connected to the housing, and a source of energy electrically connected to the thermoelectric assembly. The thermoelectric assembly includes a pair of heat sinks and a Peltier effect device capable of creating warming and cooling configurations. The Peltier device includes a pair of insulated materials spaced apart in a parallel configuration and a plurality of semiconductors sandwiched between the pair of insulated materials. The semiconductors are electrically connected in series by electrical conductors, and the conductor members are electrically connected to the energy source. Ventilation holes and a fan are optional.

In use, the temperature controlled input device generates and transmits data signals to the computer in a conventional manner. Electricity flows in series through the semiconductors and the electrical conductors, inducing a temperature differential between the first and second heat sinks which extend outside the housing. This heats the first heat sink and cools the second heat sink. By simply reversing the current direction, the first heat sink is cooled and the second heat sink is heated. The user selects the direction and amount of current flow through a switch, a thermostat, remotely through the computer, or by a like method. If ventilation holes and a fan are used, the fan circulates air and aids in heating and cooling the input device. The end result is a controlled microclimate that can selectively warm or cool the user's hands in a safe and effective manner.

Therefore, a general object of this invention is to provide a temperature controlled input device for a computer that can selectively warm or cool the user's hands.

Another object of this invention is to provide a temperature controlled input device for a computer, as aforesaid, that is safe and effective.

Still another object of this invention is to provide a temperature controlled input device for a computer, as aforesaid, that is efficient enough that the amount of power needed to operate the temperature control mechanism is relatively small.

Other objects and advantages of this invention will become apparent from the following description taken in connection with the accompanying drawings, wherein is set forth by way of illustration and example, embodiments of this invention.

### BRIEF DESCRIPTION OF THE DRAWINGS

FIG. 1 is a front perspective view of a temperature controlled input device for a computer according to a now preferred embodiment of the present invention;

FIG. 2 is an exploded view of the temperature controlled input device for a computer as in FIG. 1;

FIG. 3 is an exploded view of a temperature controlled input device for a computer according to another embodiment of the present invention;

FIG. 4a is a top view of a temperature controlled input device for a computer according to still another embodiment of the present invention;

FIG. 4b is a sectional view taken from FIG. 4a;

FIG. 4c is a front perspective view of the temperature controlled input device for a computer as in FIG. 4a; and

FIG. 5 is an isolated sectional view of a thermoelectric assembly and two heat sinks of the temperature controlled input device for a computer taken from FIG. 4a.

### DESCRIPTION OF THE PREFERRED EMBODIMENT

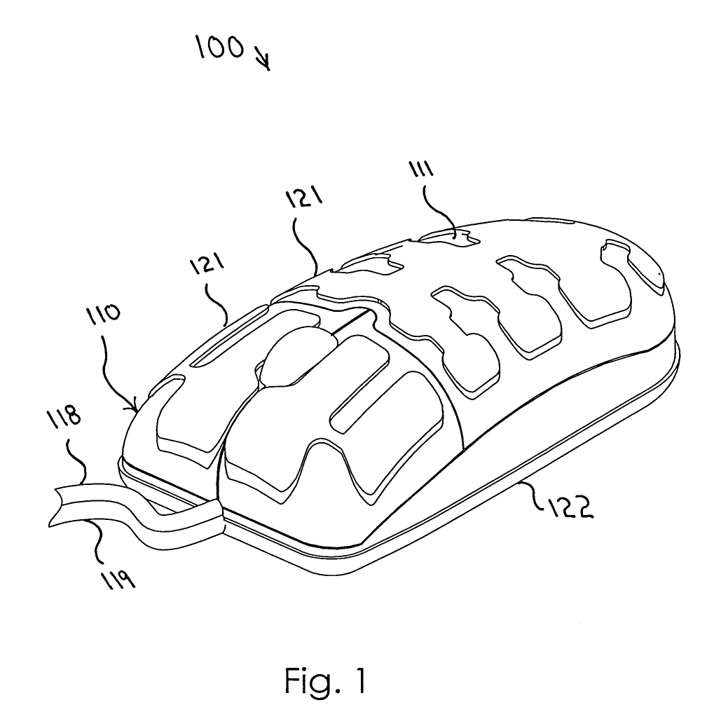

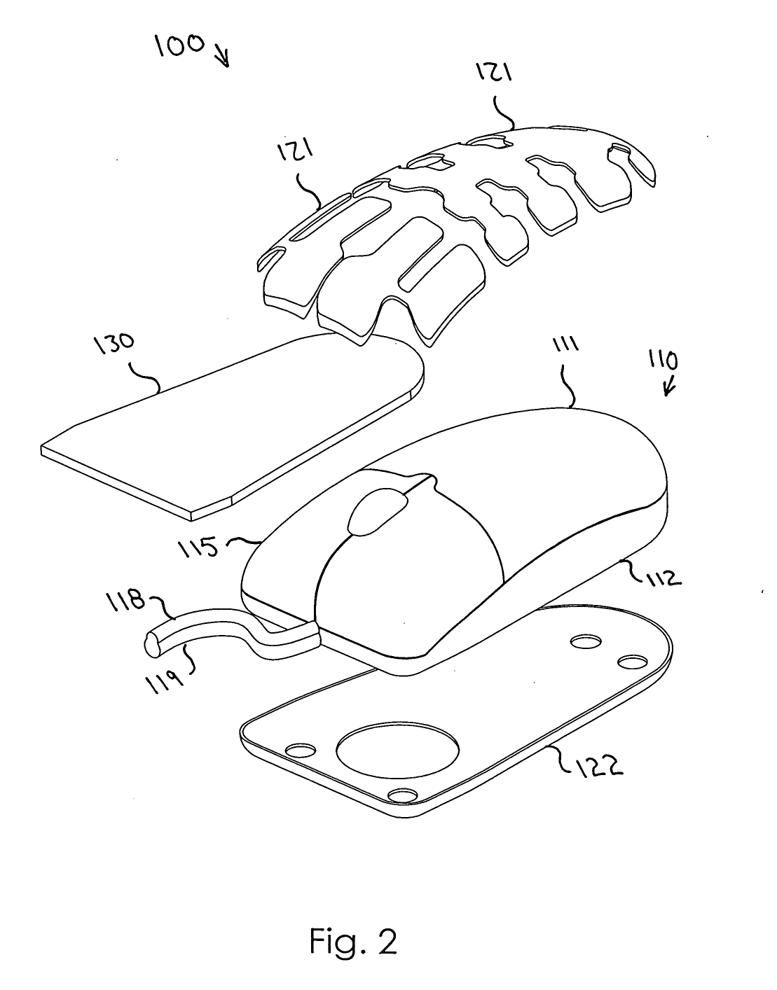

A temperature controlled input device for a computer according to one embodiment of the present invention will now be described in detail with reference to FIGS. 1 and 2 of the accompanying drawings. More particularly, a temperature controlled input device 100 according to a now preferred embodiment includes a housing 110 having at least one manually manipulative mechanism 115 for generating data signals for transmission to the computer, a thermoelectric assembly 120 connected to the housing 110, and a source of energy electrically connected to the thermoelectric assembly 120.

The housing 110 has opposed first (top) and second (bottom) exterior surfaces 111, 112. The housing 110 is shown in FIGS. 1 and 2 as a very simple mouse design, but any number of the newer body styles could be employed.

The thermoelectric assembly 120 includes a first heat transfer plate 121 attached to the first exterior surface 111, a Peltier effect device 130 positioned in an interior space in the housing 110, and a second heat transfer plate 122 connected to the second exterior surface 112. The first and second heat transfer plates 121, 122 may also be referred to as the first and second heat sinks 121, 122.

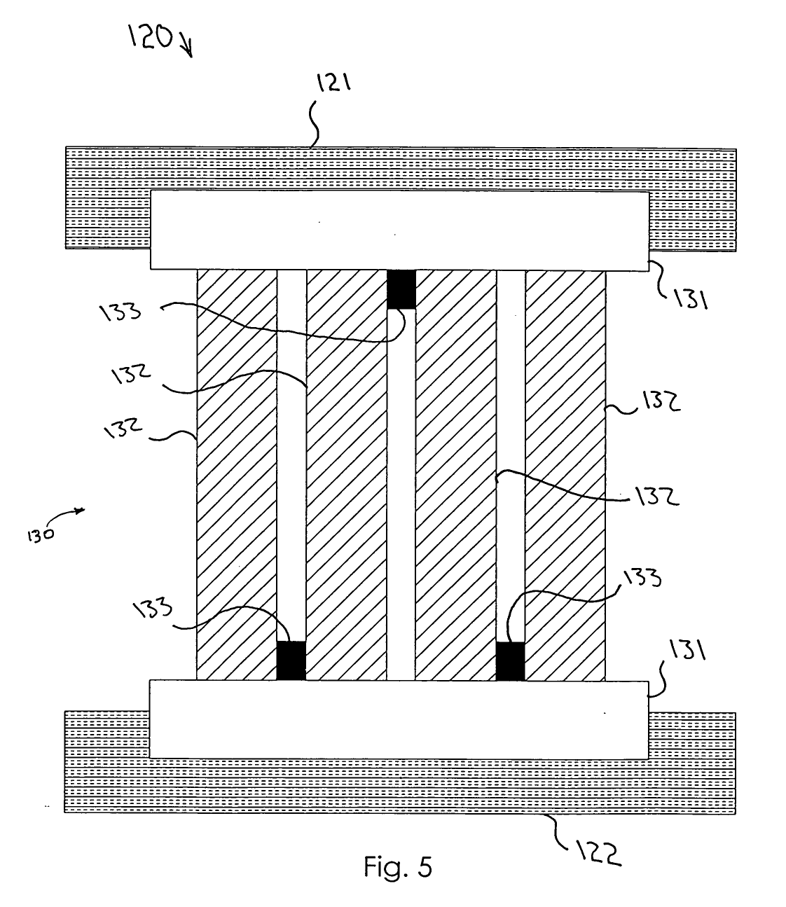

Thermoelectrics and the Peltier effect device 130 are based on the Peltier Effect, discovered in 1834, by which current applied across two dissimilar materials causes a temperature differential. The Peltier effect device 130 can be seen in FIG. 5 and includes a pair of insulated materials 131 (typically ceramic wafers) spaced apart in a parallel configuration and a plurality of semiconductors 132 sandwiched between the pair of insulated materials 131. The semiconductors 132 are arranged to alternate positive and negative semiconductors and are electrically connected in series by electrical conductors 133. The conductor members 132, 133 are electrically connected to the energy source. The semiconductors 132 induce a temperature differential between the first and second heat sinks 121, 122 when energized, thus heating the first heat sink 121 and cooling the second heat sink 122. By simply reversing the current direction, the first heat sink 121 is cooled and the second heat sink 122 is heated.

To transfer the heat from or to the user's hand, the user will need to be in contact with the first heat sink 121. This is most easily accomplished by placing the first heat sink 121 in thermal contact with both the user and the Peltier effect device 130. The first heat sink 121 is preferably a metallic plate. While the edges and curves in the first heat sink 121 shown in FIGS. 1 and 2 are not strictly necessary, they do spread out the heating or cooling power of the Peltier effect device 130 to the user's whole hand without trying to change the temperature of the entire first exterior surface 111. The first heat sink 121 can be arranged in a variety of visually pleasing configurations, including cartoon figures, team mascots, text, advertisements, etc.

While the first heat sink 121 keeps the area that contacts the user at a comfortable temperature, the second heat sink 122 must be provided with an outlet for its effects. In the heating mode (also called the warming configuration), the second heat sink 122 will be at a low temperature and must pick up heat from the surroundings to fuiction. If the second heat sink 122 were enclosed inside the housing 110, very high and low temperatures would result. In cooling mode (also called the cooling configuration) the circuitry inside the housing 110 would be exposed to high temperatures, possibly leading to electronics failures. Placing the second heat sink 122 outside of the housing 110 solves these problems. Since nearly the entire top surface 111 of the housing 110 can be in contact with the user's hand, only the bottom 112 and sides of the housing 110 are available. As much of the sides of the housing 110 as possible should be devoted to the second heat sink 122, as that is the portion open to air, but the bottom 112 of the housing 110 may also be used by the second heat sink 122.

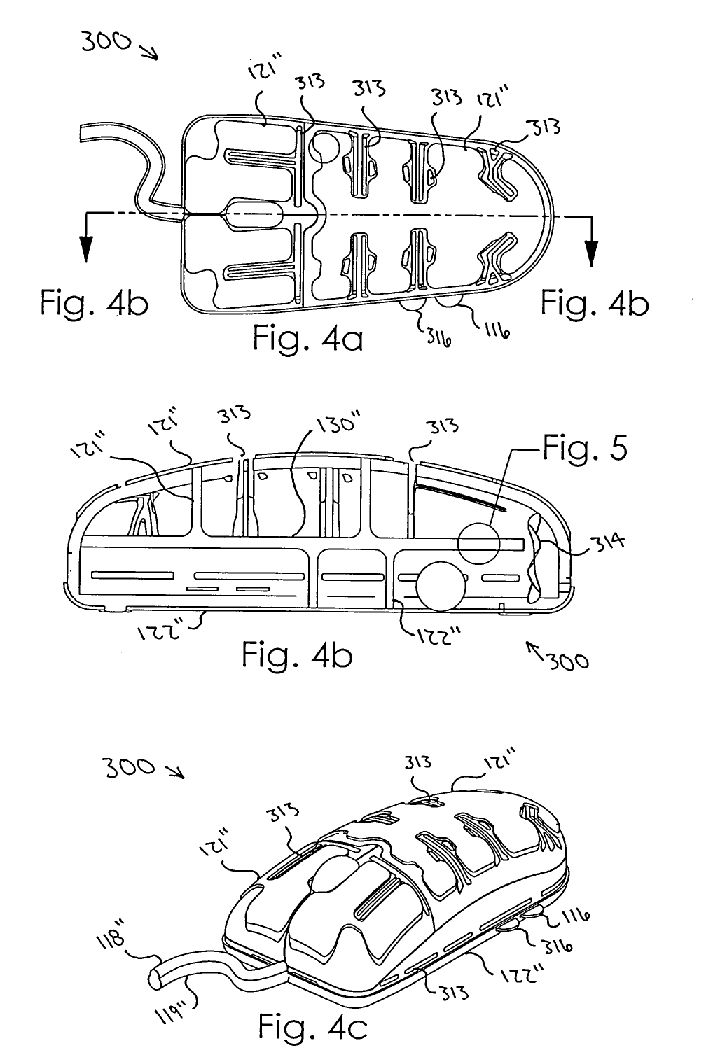

There are multiple ways to change from heating mode to cooling mode. A switch 116 mounted conveniently on the housing 110 could be used to control and reverse the direction of current going through the Peltier effect device 130 (FIG. 4c). A thermostat (not shown) could sense the ambient room temperature and act accordingly. This would automatically create a comfortable atmosphere without the user interfering. Where the thermostat was set to begin each stage might be preset or could vary. Instead of placing a physical switch 116 on the housing 110, the direction of current or the thermostat setting could be changed remotely from the computer. The driver for the temperature controlled input device 100 could include a routine that reverses the current direction when prompted to do so. For remotely controlling the temperature of the input device 100, circuitry would be included in the housing 110.

While certain computer configurations are able to supply almost 100 mW of electrical power through common computer ports, other setups can deliver less than fifty. Even with the generous assumption of a 100 mW power source, many computer input devices can use nearly all of this power. To provide any appreciable heating or cooling power, the signal lines of the computer port are not sufficient. Another power source is needed, and this can be most easily accomplished by running an auxiliary power line 118 along with the ordinary signal wire 119. This separates the delicate information channels from any spikes and heavy electrical loads. While using the auxiliary power line 118 to connect to a conventional AC power outlet is currently preferred, it is possible to supply more electrical power through common computer ports than is currently done, and batteries may be suitable.

In use, the temperature controlled input device 100 is connected to a computer by the ordinary signal wire 119 and connected to a conventional AC power source by the auxiliary power line 118. Data signals are generated and transmitted to the computer in a conventional manner. Electricity flows in series through the semiconductors 132 and the electrical conductors 133, inducing a temperature differential between the first and second heat sinks 121, 122, thus heating the first heat sink 121 and cooling the second heat sink 122. By simply reversing the current direction, the first heat sink 121 is cooled and the second heat sink 122 is heated. The user selects the direction and amount of current flow in a manner discussed above or by a like method. The end result is a controlled microclimate that can selectively warm or cool the user's hands in a safe and effective manner.

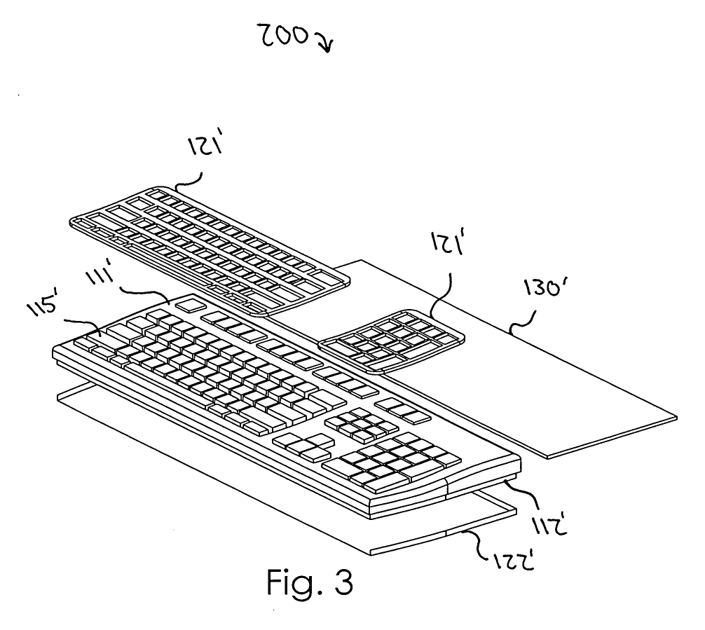

A temperature controlled computer input device 200 according to another embodiment of the present invention is shown in FIG. 3 and includes a construction substantially similar to the construction previously described except as specifically noted below. Structures having identical fimction to those described previously are shown in FIG. 3 as primed numerals. More particularly, the temperature controlled computer input device 200 according to this embodiment includes a housing 110′ shown as a very simple keyboard design, but any number of the newer body styles could be employed. The keyboard has a very large area in which to generate and dissipate heat and would seem to be ideal for the present invention. In fact, the present invention is not limited to specific types of computer input devices, as many types of input devices besides those mentioned would be suitable, such as trackballs.

A temperature controlled computer input device 300 according to still another embodiment of the present invention is shown in FIGS. 4a through 5 and includes a construction substantially similar to the construction previously described except as specifically noted below. Structures substantially similar to those first described above are shown as double primed numerals. More particularly, the temperature controlled computer input device 300 according to this embodiment includes ventilation holes 313 and fan 314 in the housing 110″. The fan 314 blows air over the heat sinks 121″, 122″ to circulate air and transmit heat through convection. The circulating air can also assist in cooling, as sweat will evaporate from the hand and be carried away by the moving air. An additional switch 316 is shown on the housing 110″ to control the fan 314, but this too can be controlled by a thermostat or remotely by computer. Though the housing 110″ is shown as a mouse, the ventilation holes 313 and the fan 314 may be used in other housings 110″, such as keyboards or trackballs, for example. FIG. 5 depicts the Peltier effect device 130 as discussed above. It is important to remember that the heat sinks 121″, 122″ shown in FIG. 5 must extend outside the housing 110″ as shown and as explained above.

It is understood that while certain forms of this invention have been illustrated and described, it is not limited thereto except insofar as such limitations are included in the following claims and allowable fimctional equivalents thereof.

1. A temperature controlled input device for use with a computer for maintaining a computer user's hand and fingers at a comfortable temperature, comprising:
a housing having at least one manually manipulative mechanism for generating data signals for transmission to the computer, said housing having opposed first and second exterior surfaces;
a thermoelectric assembly connected to said housing for warming one of said first and second exterior surfaces and for cooling another of said first and second exterior surfaces; and
a source of energy electrically connected to said thermoelectric assembly for energizing said thermoelectric assembly.

2. The input device as in claim 1 further comprising means for switching said thermoelectric assembly between a warming configuration in which said first exterior surface is warmed and said second exterior surface is cooled and a cooling configuration in which said first exterior surface is cooled and said second exterior surface is warmed.

3. The input device as in claim 2 wherein said means for switching said thermoelectric assembly between said warming configuration and said cooling configuration includes a switch for selectively reversing the direction of electrical current flowing through said thermoelectric assembly.

4. The input device as in claim 1 wherein said thermoelectric assembly includes:
a first heat transfer plate attached to said first exterior surface;
a Peltier effect device positioned in an interior space of said housing; and
a second heat transfer plate connected to said second exterior surface.

5. The input device as in claim 4 wherein said first heat transfer plate includes a metallic construction and having a configuration partially covering said first exterior surface.

6. The input device as in claim 5 wherein said first heat transfer plate is further configured in a visually pleasing configuration.

7. The input device as in claim 1 wherein said thermoelectric assembly includes:
a first heat sink attached to said first exterior surface;
a Peltier effect device positioned in an interior space of said housing; and
a second heat sink connected to said second exterior surface.

8. The input device as in claim 7 wherein said Peltier effect device includes:
a pair of insulated materials spaced apart in a parallel configuration;
a plurality of semiconductors sandwiched between said pair of insulated materials and electrically connected in series; and
a plurality of conductor members arranged along said pair of insulated materials and including means for electrically connecting said semiconductors, said conductor members being connectable to said source of electrical energy for energizing said conductor members such that said semiconductors induce a temperature differential between said first and second heat sinks when energized by said conductors.

9. The input device as in claim 1 further comprising a thermostat for maintaining said first exterior surface at a constant temperature.

10. The input device as in claim 1 further comprising circuitry for remotely controlling the temperature of said first exterior surface.

11. The input device as in claim 1 wherein said housing defines a plurality of ventilation holes.

12. The input device as in claim 11 further including at least one fan positioned in said housing for circulating air.

13. The input device as in claim 1 wherein said housing is a mouse.

14. The input device as in claim 1 wherein said housing is a keyboard.

15. A temperature controlled input device for use with a computer for maintaining a computer user's hand and fingers at a comfortable temperature, comprising:
a housing having at least one manually manipulative mechanism for generating data signals for transmission to the computer, said housing having opposed first and second exterior surfaces;
a thermoelectric assembly connected to said housing, said thermoelectric assembly including a first heat sink attached to said first exterior surface, a Peltier effect device positioned in an interior space of said housing, and a second heat sink connected to said second exterior surface;
a source of energy electrically connected to said thermoelectric assembly for delivering a current to said thermoelectric assembly, whereby to energize said thermoelectric assembly; and
means for switching said thermoelectric assembly between a warming configuration in which said first exterior surface is warmed and said second exterior surface is cooled and a cooling configuration in which said first exterior surface is cooled and said second exterior surface is warmed.

16. The input device as in claim 15 wherein said Peltier effect device includes:
a pair of insulated materials spaced apart in a parallel configuration;
a plurality of semiconductors sandwiched between said pair of insulated materials and electrically connected in series; and
a plurality of conductor members arranged along said pair of insulated materials and including means for electrically connecting said semiconductors, said conductor members being connectable to said source of electrical energy for energizing said conductor members such that said semiconductors induce a temperature differential between said first and second heat sinks when energized by said conductors.

17. The input device as in claim 15 wherein said means for switching said thermoelectric assembly between said warming configuration and said cooling configuration includes a switch for selectively reversing the direction of said current being delivered to said thermoelectric assembly.

18. The input device as in claim 17 wherein said housing defines a plurality of ventilation holes.

19. The input device as in claim 17 further comprising a thermostat for maintaining said first heat sink at a constant temperature.

20. The input device as in claim 17 further comprising circuitry for remotely controlling the temperature of said first heat sink.
